(19) United States
(12) Patent Application Publication
(10) Pub. No.: US 2012/0202010 A1
(43) Pub. Date: Aug. 9, 2012

(54) GLASS LAMINATE, GLASS LAMINATE MANUFACTURING METHOD, DISPLAY PANEL MANUFACTURING METHOD, AND DISPLAY PANEL OBTAINED BY MEANS OF DISPLAY PANEL MANUFACTURING METHOD

(75) Inventor: Daisuke UCHIDA, Tokyo (JP)

(73) Assignee: Asahi Glass Company, Limited

(21) Appl. No.: 13/451,518

(22) Filed: Apr. 19, 2012

Related U.S. Application Data
(63) Continuation of application No. PCT/JP2010/067900, filed on Oct. 12, 2010.

(30) Foreign Application Priority Data
Oct. 20, 2009 (JP) 2009-241797

(51) Int. Cl. B32B 3/02; H01L 33/48; B32B 37/10; B32B 38/10; B32B 17/06; B32B 7/02

(52) U.S. Cl. 428/157; 428/428; 428/215; 156/285; 156/281; 156/701; 428/426; 438/34; 257/E33.056

(57) ABSTRACT

The present invention relates to a glass laminate including a glass substrate and a supporting glass plate, in which a surface of the glass substrate and a surface of the supporting glass plate are directly contacted to each other, in which each of the surface of the glass substrate and the surface of the supporting glass plate that are contacted to each other is a smooth flat surface, and the both surfaces are closely adhered.

### TECHNICAL FIELD

The present invention relates to a glass laminate, a production method thereof, a production method of a display panel, and a display panel obtained by the production method.

### BACKGROUND ART

In recent years, reduction of the thickness and weight of a display panel such as liquid crystal panels (LCD), organic EL panels (OLED), plasma display panels (PDP) and field emission display panels (FED) is advanced, and reduction of the thickness of a glass substrate used in a display panel is advanced. In the case where strength of a glass substrate is insufficient due to reduction of the thickness, handling property of a glass substrate is deteriorated in a production process of a display panel.

In view of the above, a method of forming a member for a display panel on a glass substrate having a thickness larger than the final thickness, and then subjecting the glass substrate to a chemical etching treatment to reduce the thickness is conventionally widely employed. However, in this method, in the case of reducing the thickness of one glass substrate from 0.7 mm to 0.2 mm or 0.1 mm, most of original materials of the substrate is scraped off by an etching liquid. This is not preferred in the standpoints of productivity and efficiency in the use of raw materials.

Furthermore, in the method of reducing a thickness of a glass substrate by chemical etching, in the case where fine scratches are present on a surface of a glass substrate, there was a case that fine depressions (etchpits) are formed starting from scratches by the etching treatment, leading to optical defects.

To solve the above problems, Patent Documents 1 and 2 propose a method of laminating a glass substrate having small thickness and a supporting glass plate, forming a member for a display panel on the glass substrate in the state of fixing the glass substrate and the supporting glass plate, and then peeling the supporting glass plate from the glass substrate.

In the production method of a display panel, as a method of laminating the glass substrate and the supporting glass plate, and fixing those, Patent Document 1 proposes a method of interposing O-ring between the glass substrate and the supporting glass plate, and sucking under vacuum between those glass plates, and Patent Document 2 proposes a method of interposing a resin layer having repeelability between the glass substrate and the supporting glass plate, and fixing those by close adhesion force of the resin layer.

### BACKGROUND ART DOCUMENTS

### Patent Document

Patent Document 1: JP-A-2000-241804
Patent Document 2: WO 08/007,622 pamphlet

### SUMMARY OF THE INVENTION

### Problems that the Invention is to Solve

However, in the method of interposing O-ring between the glass substrate and the supporting glass plate as proposed in Patent Document 1, the glass substrate sags by the O-ring, and it was difficult to form a member for a display panel on the glass substrate with good precision.

Furthermore, in the method of interposing a resin layer having repeelability between the glass substrate and the supporting glass plate as proposed in Patent Document 2, in the case where a thickness of the resin layer is not uniform, flatness of the glass substrate is impaired.

The present invention has been made in view of the above problems, and has objects to provide a glass laminate having excellent flatness, and a production method thereof. Furthermore, the present invention has objects to provide a production method of a display panel using the glass laminate, and a display panel obtained by the production method.

### Means for Solving the Problems

In order to solve the above-mentioned problem, a glass laminate of the present invention is a glass laminate comprising a glass substrate and a supporting glass plate, in which a surface of the glass substrate and a surface of the supporting glass plate are directly contacted to each other,

wherein each of the surface of the glass substrate and the surface of the supporting glass plate that are contacted to each other is a smooth flat surface, and the both surfaces are closely adhered.

A method for producing a glass laminate according to the present invention is a method for producing the glass laminate, the method comprising laminating the glass substrate and the supporting glass plate in reduced pressure atmosphere.

A method for producing a display panel using the glass laminate according to the present invention is a method for producing a display panel using the glass laminate described above, the method comprising:

forming a member for a display on a face of the glass substrate at the side opposite the side contacting the supporting glass plate, and

subsequently separating the glass substrate and the supporting glass plate.

A display panel of the present invention is obtained by the method for producing a display panel according to the present invention.

### Advantage of the Invention

According to the present invention, a glass laminate having excellent flatness and a production method thereof can be provided. Furthermore, according to the present invention, a production method of a display panel using the glass laminate and a display panel obtained by the production method can be provided.

### BRIEF DESCRIPTION OF THE DRAWINGS

FIG. 1 is a cross-sectional view showing a glass laminate according to one embodiment of the present invention.

FIG. 2A is a cross-sectional view showing a modification example of FIG. 1.

FIG. 2B is a plane view showing a modification example of FIG. 1.

FIG. 3 is a process chart showing a production method of a glass laminate 10.

FIG. 4A is a cross-sectional view for explaining a glass substrate setting operation of a pressing apparatus 30.

FIG. 4B is a cross-sectional view for explaining decompression operation of the pressing apparatus 30.

FIG. 4C is a cross-sectional view for explaining an operation of lamination between a glass substrate and a supporting glass plate, of the pressing apparatus 30.

FIG. 5 is a plane view showing a suction head 31.

FIG. 6 is a process chart showing one example of a production method of a liquid crystal panel.

FIG. 7 is a process chart showing one example of a production method of an organic EL panel.

FIG. 8 is a cross-sectional view for explaining a peeling test.

FIG. 9 is a cross-sectional view for explaining a shear test.

### MODE FOR CARRYING OUT THE INVENTION

In the present invention, a glass substrate means a sheet or film comprising a glass, constituting a display panel having a member for a display panel formed on the surface thereof. A supporting glass plate means a sheet or film comprising a glass, which does not constitute a display panel. A glass laminate means a laminate of the glass substrate and the supporting glass plate, and is used in the production of a display panel. The glass laminate is used partway a display panel production process (until the glass substrate and the supporting glass plate are separated), and after the glass substrate and the supporting glass plate have been separated, the supporting glass plate is removed from the display panel production process, and does not constitute a member constituting a display panel. The supporting glass plate separated from the glass substrate can be recycled as a supporting glass plate. That is, the supporting glass plate is laminated to a fresh glass substrate, whereby a glass laminate can be obtained.

The supporting glass plate is used to hold and reinforce the glass substrate, and to prevent deformation, scratches, breakage and the like of the glass substrate in the course of a display panel production. Furthermore, in the case of using a glass substrate having a thickness smaller than that of the conventional glass substrate, in order to apply to a display panel production process adapted to a glass substrate having the conventional thickness, a glass laminate having the same thickness as that of the conventional glass substrate is formed, whereby a thin glass substrate can be used. This is one of the objects to use the supporting glass plate.

In the present invention, the member for a display means a member of constituting a display panel by being formed on a surface of the glass substrate, or a part thereof. The member for a display panel formed on the surface at the glass substrate side (that is, exposed glass substrate surface) of the glass laminate may not be all of members previously formed on the glass substrate and constituting the display panel (hereinafter referred to as the “all member” for simplicity). The reason for this is that a glass substrate having a member for a display panel (partial member) attached thereto separated from the glass laminate can be made a glass substrate having a member for a display panel (all member) attached thereto in the subsequent step. Thereafter, a display panel is produced using the glass substrate having a member for a display panel (all member) attached thereto. Furthermore, other member for a display panel may be formed on its separation face of the glass substrate having a member for a display panel (all member or partial member) separated from the glass laminate. Furthermore, a display panel can be produced by fabricating a display panel using the glass laminate having a member for a display (all member) and then separating the supporting glass plate. Furthermore, a display panel can be produced by fabricating a display panel using two glass laminates having a member for a display panel (all member) attached thereto and then separating two supporting glass plates.

In the present invention, the display panel means display panels such as liquid crystal panels (LCD), organic EL panels (OLED), plasma display panels (PDP) and field emission display panels (FED). The display panel has one or two glass substrates as its constituting member. As the case may be, the display panel has three or more glass substrates. In the present invention, the display panel is produced using a glass substrate having a member for a display panel attached thereto (a glass substrate obtained using the glass laminate of the present invention). In the case that a plurality of glass substrates constituting the display panel is present, a part of a plurality of the glass substrates used in the production of a display panel may not be a glass substrate having a member for a display panel attached thereto obtained using the glass laminate of the present invention, and may be other glass substrate. For example, the display panel can be produced by using a glass substrate having a member for a display attached thereto produced without through the glass laminate of the present invention or a glass substrate on which a member for a display is not formed, as a part of the glass substrate.

In the present invention, in laminating the glass substrate and the supporting glass plate to form a glass laminate, a glass substrate surface and a supporting glass plate surface that are contacted to each other are called a lamination plane of the glass substrate and a lamination plane of the supporting glass plate, respectively. A face opposite the lamination plane of the glass substrate is called a non-lamination plane of the glass substrate, and a face opposite the lamination plane of the supporting glass plate is called a non-lamination plane of the supporting glass plate. Furthermore, a main surface of a side becoming the lamination plane of the glass substrate is called a first main surface (of the glass substrate), and a main surface of a side becoming the lamination plane of the supporting glass plate is called a first main surface (of the supporting glass plate). Similarly, a main surface of a side becoming the non-lamination plane of the glass substrate is called a second main surface (of the glass substrate), and a main surface of a side becoming the non-lamination plane of the supporting glass plate is called a second main surface (of the supporting glass plate).

The glass substrate and the supporting glass plate each are obtained by melting glass raw materials and molding the molten glass into a sheet shape. The molding method may be a general method, and for example, a float process, a fusion process, a slot down draw process, a Fourcault process and a Lubbers process are used. Furthermore, a particularly thin plate is obtained by a process (redraw process) of heating a glass once molded into a sheet shape, and drawing the sheet-like glass by the means such as stretching to reduce the thickness.

Glass that is a material of the glass substrate and the supporting glass plate is preferably a borosilicate glass, a soda lime glass, a high silica glass, and an oxide glass comprising other silicon oxide as a main component. The oxide glass is preferably a glass having a silicon oxide content of from 40 to 90 mass % in terms of an oxide. A glass for a glass substrate is that glass characteristics required differ depending on the kind of a display panel. Therefore, a glass satisfying the requirement is used. In a glass for a supporting glass plate, the restriction of glass characteristics required is small. However, in the case that a glass laminate is heat-treated in the formation of a member for a display panel, a glass having small difference in thermal expansion coefficient to that of a glass of the glass substrate is preferably used. In particular, a glass of the supporting glass plate is preferably the same glass as the glass substrate for the reasons that difference in thermal expansion coefficient is small and other properties are equivalent.

As the glass of the glass substrate, a glass matching glass characteristics required by the kind of a display panel is used. With regard to a glass substrate for a liquid crystal panel (LCD), since elution of an alkali metal component easily affects liquid crystal, the glass substrate comprises a glass free of an alkali metal component (non-alkali glass) or a glass having small alkali metal content (low alkali glass). Thus, the glass of the glass substrate is appropriately selected based on a display panel applied and its production process.

The glass of the glass substrate is particularly preferably a glass having low thermal expansion coefficient. Formation of a member for a display on a glass substrate surface involves many heat treatments. In the case where the thermal expansion coefficient of the glass of the glass substrate is large, various disadvantages easily occur in the heat treatment. For example, in the case of forming a thin film transistor (TFT) on a glass substrate, when the glass substrate having TFT formed thereon under heating is cooled, positional deviation of TFT may be excessive by heat shrinkage of the glass substrate. As an index of the thermal expansion coefficient of a glass in the present invention, an average linear expansion coefficient as defined in JIS R 3102-1995 is used. The average linear expansion coefficient at from 25 to 300° C. of the glass of the glass substrate is preferably from 0 to 50×10⁻⁷/° C., and more preferably 0 to 40×10⁻⁷/° C. The upper limit 300° C. of the temperature corresponds to the upper limit of a temperature applied to a glass substrate in the ordinary production of a display panel.

The glass of the supporting glass plate preferably uses a glass having difference in an average linear expansion coefficient at from 25 to 300° C. to the glass of the glass substrate of 15×10⁻⁷/° C. or less. In the case where difference in an average linear expansion coefficient at from 25 to 300° C. between the glass of the glass substrate and the glass of the supporting glass plate is too large, there are possibilities that a glass laminate vigorously warps and the glass substrate and the supporting glass plate are peeled, when heating and cooling in the production process of the display panel. In the case that the glass of the glass substrate and the glass of the supporting glass plate are the same glass, there is no possibility of occurrence of such a problem.

The thickness of the glass substrate is not particularly restricted, but from the standpoints of reduction of thickness and/or reduction of weight, the thickness is generally less than 0.8 mm, preferably 0.3 mm or less, and further preferably 0.15 mm or less. In the case where the thickness is 0.8 mm or more, the requirement of reduction of thickness and/or reduction of weight is not satisfied. When the thickness is 0.3 mm or less, good flexibility can be given to the glass substrate. When the thickness is 0.15 mm or less, the glass substrate can be wound in a roll form. Furthermore, the thickness is preferably 0.04 mm or more for the reasons that handling of the glass substrate is easy, and the like.

The thickness of the supporting glass plate is preferably 0.08 mm or more for the reasons that the supporting glass plate is easy to handle and is difficult to be broken, in producing a display panel using the supporting glass plate. The thickness of supporting glass plate may be larger or smaller than the thickness of the glass substrate. Preferably, the thickness of the supporting glass plate is selected from the thickness of the glass substrate selected from the above range and the thickness of a glass laminate described hereinafter, according to the purpose.

The size and shape of the glass substrate are selected according to the size and shape of a display panel. In general, the shape of display panel is a rectangular shape, and therefore, the shape of the glass substrate is generally a rectangular shape. The size and shape of the supporting glass plate used are generally nearly the same as the size and shape of the glass substrate. The size of the supporting glass plate is preferably the same as or slightly larger than the size of the glass substrate from the standpoint of supporting the glass substrate. That is, external dimensions of the first main surface of the supporting glass plate are preferably the same as or larger than external dimensions of the first main surface of the glass substrate.

The first embodiment of the present invention is described below by reference to the drawings. In each drawing, to make the drawing more visible, the proportional relation of the shape of the glass laminate is overdrawn.

In the present embodiment, the formation step of a member for a display panel is described in the case that the temperature of the glass laminate does not exceed 300° C.

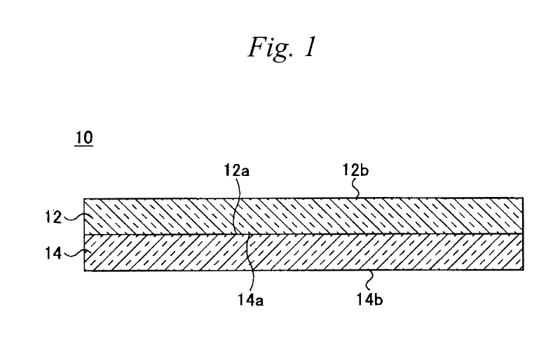

FIG. 1 is a cross-sectional view showing the glass laminate in the first embodiment of the present invention. As shown in FIG. 1, a glass laminate 10 is a laminate of a glass substrate 12 and a supporting glass plate 14. A lamination plane (first main surface) 12a of the glass substrate 12 is directly contacted with a lamination plane (first main surface) 14a of the supporting glass plate 14, and both surfaces are closely adhered to each other. The glass laminate 10 itself has two surfaces. One surface comprises a non-lamination plane (second main surface) 12b of the glass substrate 12 (the surface of the glass laminate is hereinafter referred to as a glass substrate surface 12b), and other surface comprises a non-lamination plane (second main surface) 14b of the supporting glass plate 14.

In the glass laminate of the present invention, the constitution that the lamination planes 12a and 14a of both glass plates 12 and 14 are closely adhered means that a member for a display panel is formed on the glass substrate surface 12b of the glass laminate, and the lamination plane 12a and the lamination plane 14a are contacted with a bonding force of such an extent that the glass substrate and the supporting glass plate are not separated until reaching the stage of separating the glass substrate and the supporting glass plate. Furthermore, the bonding force of the lamination plane must be a bonding force of such an extent that both glass plates 12 and 14 are easily separated when an operation for separating the glass substrate and the supporting glass plate is conducted.

The bonding force is preferably a bonding force that peel strength is 0.2 N/cm or more in a peeling test described hereinafter form the reason that, for example, it is easy to handle in the production process of a display panel. Furthermore, the bonding force is preferably a bonding force that peel strength is 100 N/cm or less in a peeling test described hereinafter form the standpoint that the glass substrate 12 and the supporting glass plate 14 can easily be separated. The bonding force is more preferably a bonding force that the peel strength is 50 N/cm or less, and further preferably a bonding force that the peel strength is 40 N/cm or less. In the case where the bonding force between the lamination planes 12a and 14a is excessive, one of or both the glass substrate 12 and the supporting glass plate 14 may be damaged in the separation.

It is generally known that when glass plates are laminated with each other, glass surfaces are bonded at a lamination plane, and are closely adhered with a certain degree of bonding force. It is considered that the bonding force is due to hydrogen bond between silanol groups (Si—OH) present on both glass surfaces, formation of chemical bond by partial dehydrocondensation, van der Waals force between both glass surfaces, and the like. In the glass laminate of the present invention, the lamination planes 12a and 14a are not fused (“fused” means glasses are melted and bonded). In the case where the lamination surfaces are fused, bonding force of the lamination plane is excessively high, and the separation between the glass substrate and the supporting glass plate becomes difficult.

In general, the glass laminate is often heated to about 300° C. in forming a member for a display panel on the glass substrate surface 12b. The glass laminate of the present invention is that separation between the glass substrate and the supporting glass plate does not become difficult even passing through the heating in such a degree. Dehydrocondensation reaction between silanol groups (Si—OH) is accelerated by heating. However, it is considered that in the heating at about 300° C., chemical bond is difficult to be formed by dehydrocondensation reaction between silanol groups of both glass surfaces, and the bonding force does not become excessively high.

The bonding force between the lamination planes 12a and 14a of the glass substrate and the supporting glass plate easily change by various factors of the lamination planes 12a and 14a, but it is at least necessary for the lamination planes to be smooth flat surfaces. In the case where the both surfaces are not flat surfaces, spaces are formed between the lamination planes, and both surfaces are not closely adhered. Similarly, in the case where the both surface are not smooth, fine spaces are easily generated between the lamination planes, and both surfaces are difficult to be closely adhered. Furthermore, it is preferred that both surfaces are sufficiently clean. In the case where foreign matters such as contamination are present on the lamination plane, both surfaces are difficult to be closely adhered. Besides the above, it is considered that silanol group density of the glass surface, glass composition of the glass surface, and the like give influence. Furthermore, the respective lamination planes of the glass substrate and the supporting glass plate are not restricted to be the same, and it is considered that the bonding force changes by, for example, smoothness and a combination of lamination planes having different cleanness. Therefore, it is preferred to use the glass substrate and the supporting glass plate by appropriately adjusting such that the peel strength by the peeling test is fallen in the above range.

Each of average surface roughness of the lamination plane (first main surface) 12a of the glass substrate 12 and average surface roughness of the lamination plane (first main surface) 14a of the supporting glass plate 14 is preferably less than 1.0 nm, In the case where the average surface roughness of both lamination planes is 1.0 nm or more, substantial contact area between both surfaces becomes too small, and both surfaces cannot be closely adhered by sufficient bonding force. The surface roughness of those lamination planes is a value obtained by measuring the first main surfaces 12a and 14a becoming the respective lamination planes before laminating the glass substrate 12 and the supporting glass plate 14.

There is a case that sufficient adhesiveness is not obtained by a combination of the glass substrate 12 and the supporting glass plate 14, each having an average surface roughness of less than 1.0 nm by the factors of, for example, materials of the glass substrate 12 and the supporting glass plate 14, a combination of those materials, shapes of the glass substrate 12 and the supporting glass substrate 14, and a combination of the shapes. Therefore, it is preferred that an average surface roughness of at least one of the glass substrate and the supporting glass plate is 0.8 nm or less (the other plate may be less than 1.0 nm), and it is more preferred that an average surface roughness of both the glass substrate 12 and the supporting glass plate 14 is 0.8 nm or less. In any of the glass substrate 12 and the supporting glass plate 14, the average surface roughness of the non-lamination planes 12b and 14b is not restricted to the above range.

The average surface roughness of a glass surface in the present invention means an average value of an arithmetic average height at two points or more optionally selected. The arithmetic average height means an arithmetic average height Ra defined in JIS B 0601-2001, and is obtained by measuring a measurement region of 5 μm×5 μm at each point by an atomic force microscope.

The glass substrate and the supporting glass plate, having an average surface roughness of a first main surface thereof in the above range can be obtained by a method of smoothening a glass surface by a method such as polishing or etching. Furthermore, depending on a method for producing a glass plate, the glass substrate and the supporting glass plate, having an average surface roughness in the above range from the beginning can be produced. Furthermore, depending on the commercially available glass substrate and supporting glass plate, there are plates having already been subjected to a smoothening treatment such as polishing. Therefore, in using the glass substrate and the supporting glass plate, in the case that an average surface roughness of a surface main surface of its first main surface is measured and the average surface roughness is outside the above range, it is preferred that the plates are subjected to polishing or the like and are used as plates having the average surface roughness in the above range.

Whether the lamination planes 12a and 14a of the glass substrate 12 and the supporting glass plate 14 are sufficiently cleaned is judged by measuring a water contact angle of the first main surfaces 12a and 14a becoming the lamination planes before lamination. In general, there is a tendency that a water contact angle of a glass surface becomes large as activity (cleanness) of a glass surface is decreased. Therefore, in the case where the water contact angle of the first main surfaces 12a and 14a are too large, the activity (cleanness) of the first main surfaces 12a and 14a are too low, and as a result, the first main surfaces 12a and 14a cannot be closely adhered with sufficient bonding force.

The water contact angle of the respective first main surfaces 12a and 14a of the glass substrate and the supporting glass plate is preferably 5° or less. The water contact angle used herein means a water contact angle defined in JIS R 3257-1999. In the case where sufficient close adhesion is not obtained by the combination of the glass substrate 12 and the supporting glass plate 14, each having a water contact angle of the respective first main surfaces of 5° or less, due to factors such as materials of the glass substrate 12 and the supporting glass plate 14, a combination of those materials, shapes of the glass substrate 12 and the supporting glass plate 14, and a combination of the shapes, it is preferred that the water contact angle of at least one first main surface is 4° or less, and it is more preferred that the water contact angle of the first main surfaces 12a and 14a of the glass substrate 12 and the supporting glass plate 14 is 4° or less. In any of the glass substrate 12 and the supporting glass plate 14, the water contact angle of the non-lamination planes 12b and 14b is not limited to the above range.

The glass substrate 12 and the supporting glass plate 14, having a first main surface are preferably that the first main surfaces 12a and 14a are cleaned before lamination to form the first main surfaces having low water contact angle, and the glass substrate 12 and the supporting glass plate 14 are then laminated. The cleaning method may be general methods used in cleaning glass products. For example, wet cleaning includes ultrasonic cleaning, polishing using a polishing slurry containing abrasives such as ceria abrasives, acid cleaning using an acidic cleaning liquid containing an acid such as hydrofluoric acid or nitric acid, alkali cleaning using an alkali cleaning liquid containing a base such as ammonia or potassium hydroxide, and cleaning using a cleaning liquid containing a surfactant or other detergent. Furthermore, dry cleaning includes photochemical cleaning using ultraviolet ray or ozone, and physical cleaning using plasma. Those cleaning methods are used alone or in combination thereof. After completion of the cleaning, if necessary, drying is conducted such that a detergent does not remain.

The thickness of the glass laminate 10 (total thickness of the glass substrate 12 and the supporting glass plate 14) is preferably set such that the glass laminate 10 can be conveyed by the existing production line. For example, in the case that the existing production line is designed so as to convey a substrate having a thickness of 0.7 mm, and the thickness of the glass substrate 12 is 0.3 mm, it is preferred that the thickness of the supporting glass plate 14 is 0.4 mm. Many existing production lines are designed so as to convey a substrate having a thickness of 0.2 mm or more and 1.0 mm or less. Therefore, the thickness of the glass laminate 10 is preferably 0.2 mm or more and 1.0 mm or less.

In the glass laminate 10 of the present embodiment, the glass substrate 12 and the supporting glass plate 14 are directly contacted and closed adhered, as shown in FIG. 1. Therefore, as compared with the case that O-ring or a resin layer is interposed between both glass plates 12 and 14, the glass laminate 10 is difficult to warp. For this reason, the glass laminate has excellent flatness, and this means that the flatness of a glass substrate surface of a glass laminate is excellent.

Furthermore, in the glass laminate 10 of the present embodiment, the glass substrate 12 and the supporting glass plate 14 are directly contacted and closed adhered. Therefore, as compared with the case that a resin layer having peelability is interposed between the glass substrate 12 and the supporting glass plate 14, the number of parts can be reduced, and costs can be reduced. Furthermore, the supporting glass plate separated from the glass laminate can easily be recycled. That is, the supporting glass plate once used does not have a resin layer, and therefore can immediately be laminated with a fresh glass substrate directly or, if necessary, after cleaning or the like. Furthermore, even in the case that the supporting glass plate separated from the glass laminate is not reused, a step of peeling a resin layer from the supporting glass plate is not required as compared with the case of adhering the resin layer to the supporting glass plate and using the same. Therefore, the supporting glass plate 14 can easily be recycled as a glass material.

Furthermore, the glass laminate 10 of the present embodiment has excellent heat resistance as compared with the case that a resin layer having peelability is interposed between both glass plates 12 and 14. For example, even after heating at a temperature of 300° C. for 1 hour in the atmosphere, change of peel strength in a peeling test between the glass substrate lamination plane 12a and the supporting glass plate lamination plane 14a is slight, and bonding force between the lamination planes is maintained.

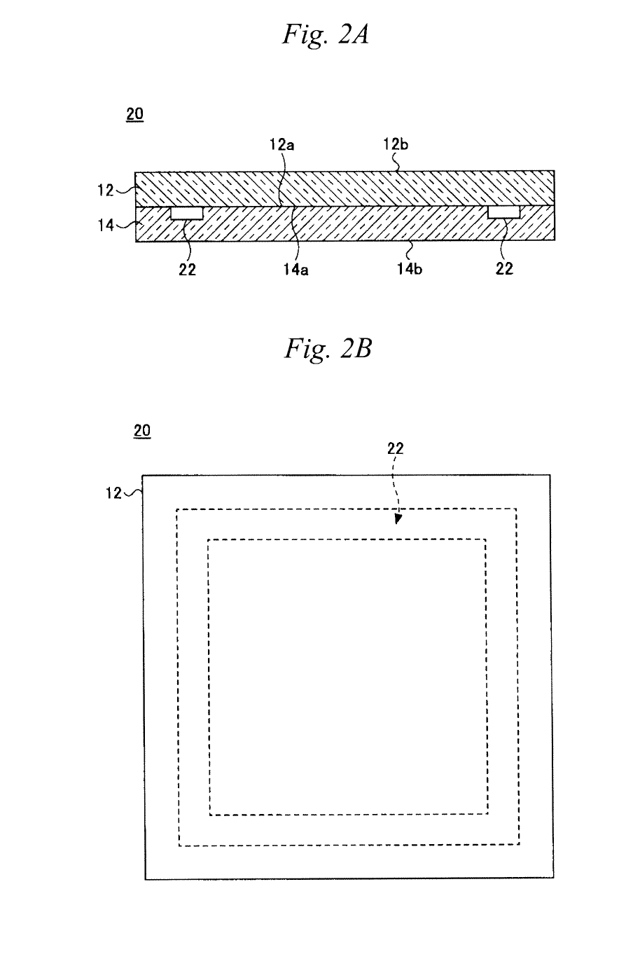

FIG. 2A is a cross-sectional view showing a modification example of FIG. 1, and FIG. 2B is a plane view showing a modification example of FIG. 1. Constitution of a glass laminate 20 shown in FIG. 2A and FIG. 2B is described below. The same constituents as in the glass laminate 10 shown in FIG. 1 have the same reference numerals and signs, and description thereof is omitted.

In the modification example shown in FIG. 2A and FIG. 2B, the supporting glass plate 14 has a depressed portion 22 in a peripheral part of its first main surface 14a. The depressed portion 22 is present in the lamination plane, is covered with the first main surface 12a of the glass substrate 12, and is sealed. The inside of the depressed portion 22 is preferably a reduced pressure atmosphere. When the inside of the depressed portion 22 is a reduced pressure atmosphere, the glass substrate 12 is sucked under vacuum to the supporting glass plate 14, making it possible to increase bonding force between the lamination planes 12a and 14a. In the case that the depressed portion 22 is formed at the central part of the supporting glass plate 14, when light enters the central part of the glass substrate 12 from the supporting glass plate 14 side using lithography technology in the production process of a display panel, the incident light receives the influence of the depressed portion 22. As a result, it becomes difficult to form a member for a display panel in good precision.

Next, a production method of the glass laminate is described.

The glass laminate of the present invention is produced by laminating a glass substrate and a supporting glass plate. The lamination is conducted by stacking the glass substrate and the supporting glass plate in a given configuration, and pressure contacting to closely adhere them. Furthermore, in the case where the glass substrate has a thickness of 0.3 mm or less, particularly 0.15 mm or less, when the glass substrate has flexibility, a lamination method used in the case of laminating a flexible plastic film on a plate surface can be used. For example, a roll lamination method that the glass substrate is pressure contacted while stacking on a supporting glass plate surface along a roll can be used. To closely adhere the first main surface of the glass substrate and the first main surface of the supporting glass plate, it is not preferred that a gas such as air remains between those surfaces. In the case where a gas remains between both first main surfaces, the gas expands when the glass laminate is heated in a production process of a display panel, and the lamination planes become easy to peel. Furthermore, there is a concern that the glass substrate locally deforms or breaks. For this reason, it is preferred to laminate the glass substrate and the supporting glass plate by a lamination method that a gas is difficult to remain between both first main surfaces.

It is preferred that the glass laminate of the present invention is produced by laminating the glass substrate and the supporting glass plate in a reduced pressure atmosphere. The lamination method is hereinafter referred to as vacuum lamination. The reduced pressure atmosphere is preferably −60 kPa or less, and more preferably −100 kPa or less, when the atmosphere is standardized as zero. In other words, when the atmosphere is not standardized as zero, the reduced pressure atmosphere is that the pressure is preferably 41.3 kPa or less, and more preferably 1.3 kPa or less.

In the case of producing the glass laminate of the present invention without limiting to the vacuum lamination, it is preferred to use the glass substrate and the supporting glass plate, that were previously subjected to polishing, cleaning or the like. For example, a glass substrate in which at least the first main surface is smooth is cleaned to provide a glass substrate in which a water contact angle of at least the first main surface is 5° or less, similarly a supporting glass plate in which at least the first main surface is smooth is cleaned to provide a supporting glass plate in which a water contact angle of at least the first main surface is 5° or less, the glass substrate and the supporting glass plate are placed in a pressing apparatus capable of reducing pressure, their first main surfaces are faced, the pressure in the pressing apparatus is reduced, and those plates are stacked and pressure-contacted to obtain a glass laminate. Particularly, in producing a glass laminate, it is preferred that both first main surfaces becoming lamination planes of the glass substrate and the supporting glass plate are previously cleaned, and those plates are laminated.

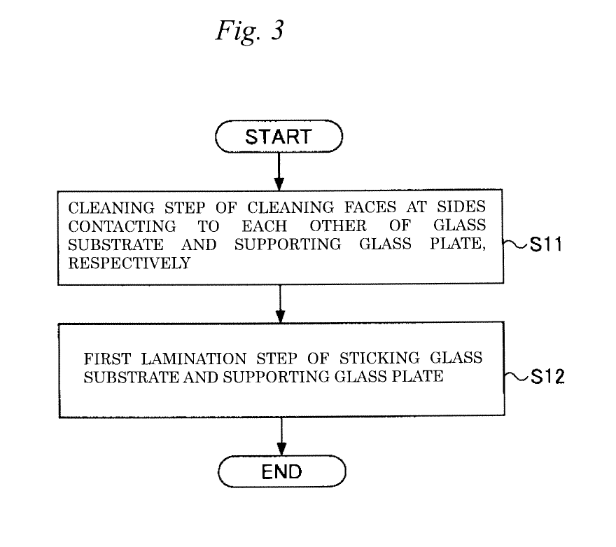

Next, a method for producing the glass laminate 10 by vacuum lamination after cleaning a glass substrate and a supporting glass plate is described by reference to FIG. 3.

FIG. 3 is a process chart showing a production method of the glass laminate 10.

The production method of the glass laminate 10 comprises:

a cleaning step of the respective first main surfaces 12a and 14a of a glass substrate 12 and a supporting glass plate 14 (step S11); and

a first lamination step of laminating the glass substrate 12 and the supporting glass plate 14 (step S12).

As the glass substrate 12 and the supporting glass plate 14, plates in which at least the respective first main surfaces 12a and 14a are smooth flat surface (flat surface in which an average surface roughness (Ra) is less than 1.0 nm) are used. In the cleaning step, at least the respective first main surfaces 12a and 14a of the glass substrate 12 and the supporting glass plate 14 are cleaned to remove particles, organic matters, and the like adhered to the first main surfaces 12a and 14a. By this, the first main surfaces 12a and 14a of the glass substrate 12 and the supporting glass plate 14 can be activated (water contact angle is 5° or less), and adhesion between the first main surfaces 12a and 14a of the both glass plates 12 and 14 can be increased. The cleaning method can use the method as described before.

In the first lamination step, the glass substrate 12 and the supporting glass plate 14 are laminated. For example, the first main surface 12a of the glass substrate 12 and the first main surface 14a of the supporting glass plate 14 are stacked, and the glass substrate 12 and the supporting glass plate 14 are pressure-contacted using a roller, a pressing apparatus or the like. By pressure-contacting, adhesion between the first main surfaces 12a and 14a of both the glass plates 12 and 14 can be increased, and additionally, gas bubbles caught between the first main surface 12a of the glass substrate 12 and the first main surface 14a of the supporting glass plate 14 can be discharged to the outside. In addition, catching of gas bubbles at the lamination can further be suppressed by the lamination in a reduced pressure atmosphere. In the case that the depressed portion 22 is formed in a peripheral part of the first main surface 12a of the glass substrate 12 as shown in FIG. 2A and FIG. 2B, the inside of the depressed portion 22 can be made a state of reduced pressure by laminating both glass plates 12 and 14 in reduced pressure atmosphere.

In the first lamination step, it is preferred that the glass substrate 12 and the supporting glass plate 14 are laminated while supporting a peripheral part of the second main surface 12b of the glass substrate 12. In the case where the central part of the second main surface 12b of the glass substrate 12 is supported, a region for forming a member for a display panel may be damaged.

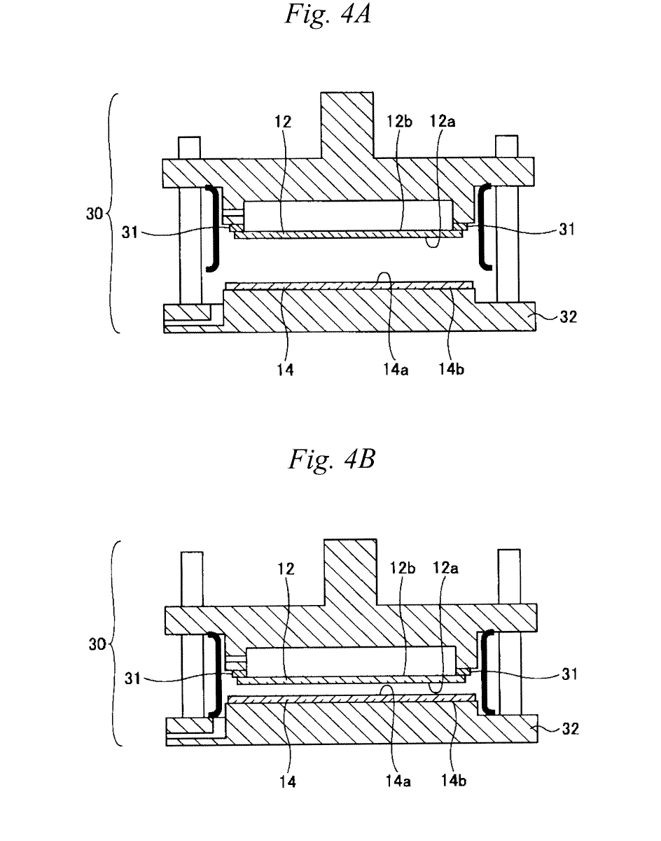

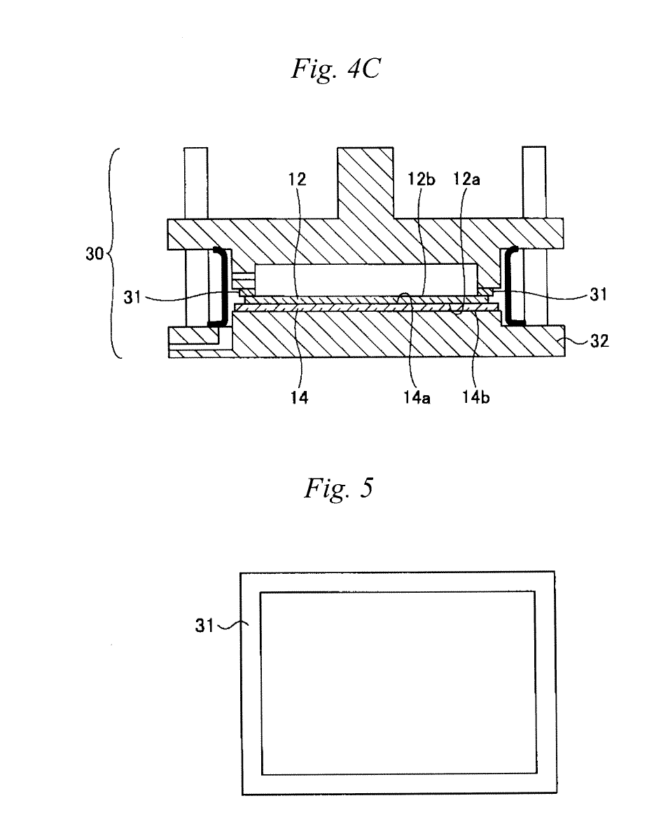

FIG. 4A is a cross-sectional view for explaining a setting operation of a glass substrate and a supporting glass plate of the pressing apparatus 30. FIG. 4B is a cross-sectional view for explaining a reducing pressure operation of the pressing apparatus 30. FIG. 4C is a cross-sectional view for explaining an operation of lamination between a glass substrate and a supporting glass plate of the pressing apparatus 30. FIG. 5 is a plane view showing a suction head 31. The pressing apparatus 30 is constituted of a suction head 31, a stage 32 and the like. The suction heat 31 has a rectangular frame shape as shown in FIG. 5.

In the pressing apparatus 30, first the glass substrate 12 after the cleaning step of FIG. 3 is placed on the stage 32 such that the second main surface 12b faces upside. Subsequently, the suction head 31 is decreased, and when the suction head 31 has contacted a peripheral part of the second main surface 12b of the glass substrate 12, the suction head 31 is stopped. Next, the glass substrate 12 is electrostatically sucked to the suction head 31 by applying voltage (for example, 2 kV) to the suction heat 31. The suction head 31 is increased in this state, and the supporting glass plate 14 after the cleaning step of FIG. 3 is placed on the stage 32 such that the first main surface 14a faces upside. FIG. 4A is a cross-sectional view of the pressing apparatus 30 at the time that the supporting glass plate 14 has been placed on the stage 32.

Thereafter, the suction head 31 is again decreased, and the glass substrate 12 and the supporting glass plate 14 are faced in a given distance (for example, 3 mm) as shown in FIG. 4B. Subsequently, pressure in a space between the glass substrate 12 and the supporting glass plate 14 is reduced to a given pressure (for example, −100 kPa (on the basis of the atmosphere)) using, for example, a vacuum pump (not shown).

The suction head 31 is decreased in this state, and the glass substrate 12 and the supporting glass plate 14 are pressure contacted at room temperature for a given period of time (for example, 180 seconds) by applying a given pressure (for example, 300 kN/m²) to the glass substrate by the suction head 31 as shown in FIG. 4C. Subsequently, the application of voltage to the suction head 31 is released, at the same time the vacuum pup is stopped, and the suction head 31 is increased. Thus, the glass laminate 10 shown in FIG. 1 can be obtained.

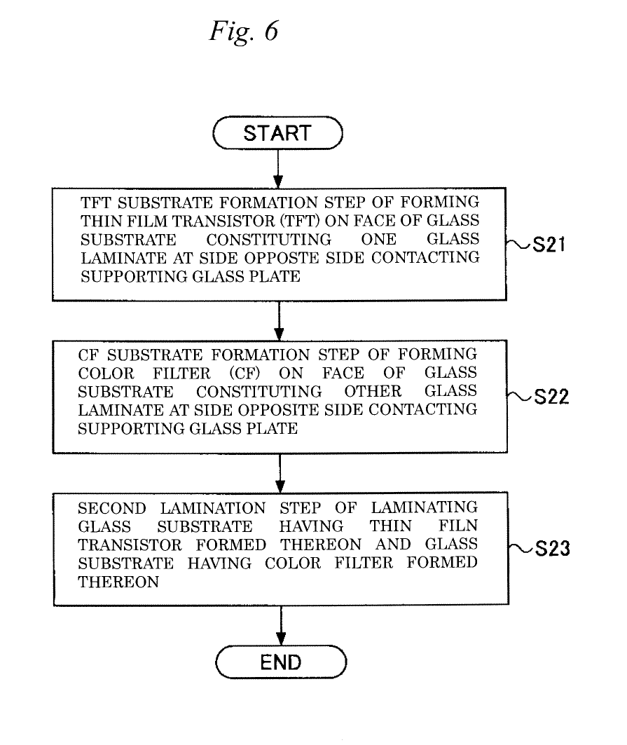

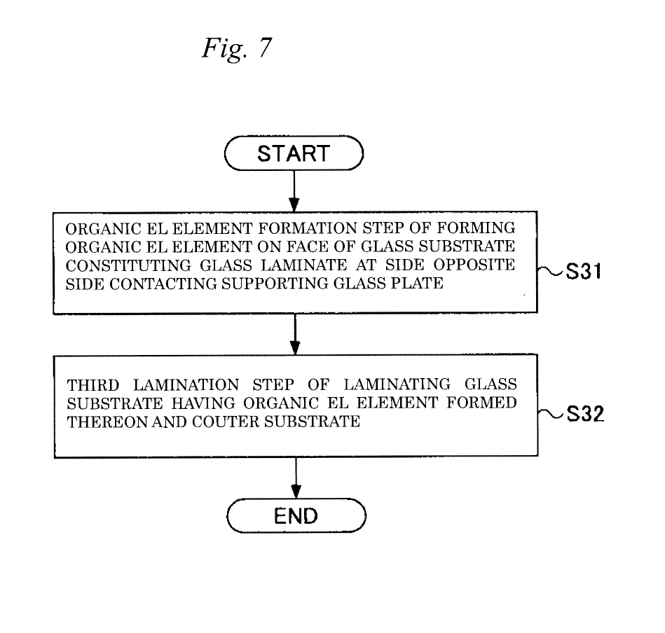

Next, a production method of a display panel is described by reference to FIG. 6 and FIG. 7.

FIG. 6 is a process chart showing one example of the production method of a liquid crystal panel (LCD). A production method of TFT-LCD is described in this embodiment, but the present invention may be applied to a production method of STN-LCD, and the kind and system of the liquid crystal panel are not restricted.

The production method of a liquid crystal panel comprises:

a TFT substrate production step of forming a thin film transistor (TFT) on the second main surface 12b of the glass substrate 12 constituting one glass laminate 10 (step S21);

a CF substrate production step of forming a color filter (CF) on the second main surface 12b of the glass substrate 12 constituting other glass laminate 10 (step S22); and

a second lamination step of laminating the glass substrate 12 having the thin film transistor fowled thereon and the glass substrate 12 having the color filter formed thereon (step S23).

In the TFT substrate production step and the CF substrate production step, TFT and CF are formed on the main second surface 12b of the glass substrate 12 using the conventional photolithography technology, etching technology and the like.

Before forming TFT and CF, the second main surface 12b of the glass substrate 12 may be cleaned if necessary. The cleaning method can use the above-described dry cleaning and wet cleaning.

The order of the TFT substrate production step and the CF substrate production step is not restricted, and the TFT substrate may be produced after producing the CF substrate.

In the second lamination step, a liquid crystal material is injected between the glass laminate 10 having TFT formed thereon (hereinafter referred to as a “glass laminate 10A”) and the glass laminate 10 having CF formed thereon (hereinafter referred to as a “glass laminate 10B”), and lamination is performed. A method for injecting a liquid crystal material includes a vacuum injection method and an instillation method.

In the vacuum injection method, for example, first both the glass laminates 10A and 10B are stuck using a sealing material and a spacer material such that a surface on which TFT is present faces a surface on which CF is present. Next, the supporting glass plates 14 and 14 are peeled from both the glass laminates 10A and 10B manually or by appropriate suction pad or knife. Thereafter, the glass laminate is cut into a plurality of cells. The inside of each cell cut is made into a reduced pressure atmosphere, a liquid crystal material is injected to the inside of each cell from an injection hole, and the injection hole is sealed. Subsequently, a polarizing plate is adhered to each cell, and a backlight and the like are incorporated. Thus, a liquid crystal panel is produced.

In the present embodiment, the supporting glass plates 14 and 14 are peeled from both the glass laminates 10A and 1013, and the glass laminate is cut into a plurality of cells. However, the present embodiment is not limited to this embodiment. For example, the supporting glass plates 14 and 14 may be peeled before sticking both the glass laminates 10A and 10B using a sealing material and a spacer material.

In the instillation method, for example, first a liquid crystal material is added dropwise to any one of both the glass laminates 10A and 10B, and both the glass laminates 10A and 1013 are then laminated using a sealing material and a spacer material such that a surface on which TFT is present faces a surface on which CF is present. Next, the supporting glass plates 14 and 14 are peeled from both the glass laminates 10A and 10B manually or by appropriate suction pad or knife. Thereafter, the glass laminate is cut into a plurality of cells. Subsequently, a polarizing plate is adhered to each cell, and a backlight and the like are incorporated. Thus, a liquid crystal panel is produced.

In the present embodiment, the supporting glass plates 14 and 14 are peeled from both the glass laminates 10A and 1013, and the glass laminate is cut into a plurality of cells. However, the present embodiment is not limited to this embodiment. For example, the supporting glass plates 14 and 14 may be peeled before adding dropwise a liquid crystal material to any one of the glass laminates 10A and 10B.

In the case where the supporting glass plate 14 is not damaged after peeling, the supporting glass plate 14 may be recycled to the lamination with other glass substrate 12. During the period until recycling, the surface of the glass substrate 14 may be covered with a protective sheet. On the other hand, in the case that the supporting glass substrate is damaged after peeling, the supporting glass substrate 14 may be recycled as a glass raw material.

The production method of a liquid crystal panel may further comprise a thickness reducing step of reducing the thickness of the glass substrate 12 by chemical etching treatment after peeling the supporting glass plate 14 from the glass substrate 12, in addition to the above steps. The first main surface 12a of the glass substrate 12 is protected by the supporting glass plate 14. Therefore, even though etching treatment is conducted, etchpits are difficult to occur.

In the example shown in FIG. 6, one glass laminate 10 is used in the respective productions of the TFT substrate and the CF substrate. However, the present invention is not limited to this embodiment. That is, the glass laminate 10 may be used in the production of only any one of the TFT substrate and the CF substrate.

FIG. 7 is a process chart showing one example of a production method of an organic EL panel (OLED).

The production method of an organic EL panel comprises:

an organic EL element formation step of forming an organic EL element on the second main surface 12b of the glass substrate 12 constituting the glass laminate 10 (step S31); and

a third lamination step of laminating the glass substrate 12 having the organic EL element formed thereon and a counter substrate (step S32).

In the organic EL element formation step, the organic EL element is formed on the second main surface 12b of the glass substrate 12 using the conventional vacuum deposition technology and the like. The organic EL element comprises a transparent electrode layer, a hole transporting layer, a light emitting layer, an electron transporting layer, and the like.

Before forming the organic EL element, the second main surface 12b of the glass substrate 12 may be cleaned, if necessary. The cleaning method can use the above-described dry cleaning and wet cleaning.

In the third lamination method, for example, first the supporting glass plate 14 is peeled from the glass laminate 10 having the organic EL element formed thereon manually or by appropriate suction pad or knife. Thereafter, the glass laminate is cut into a plurality of cells. Each cell and the counter substrate are stuck such that the organic EL element contacts the counter substrate. Thus, an organic EL display is produced.

Uses of the display panel thus produced using the glass laminate 10 are not particularly restricted. The display panel is preferably used in mobile electronic devices, for example, mobile phones, PDA, digital cameras and game machines.

Next, a second embodiment of the present invention is described.

In the above first embodiment, the case that the temperature of the glass laminate does not exceed 300° C. in the formation step of a member for a display panel was described.

On the other hand, in the present embodiment, the case that the temperature of the glass laminate exceeds 300° C. in the formation step of a member for a display panel is described.

In recent years, there is a case that the temperature of a glass laminate exceeds 300° C. in the formation step of a member for a display panel. For example, a step of forming TFT on a glass substrate surface sometimes contains a step of conducting the formation in the state that the temperature of the glass substrate is from 400 to 450° C., or a step of conducting the formation in the state that the temperature of the glass substrate is about 600° C. The step of conducting at from 400 to 450° C. includes a step of film-forming amorphous silicon on a glass substrate surface, a step of removing hydrogen contained in the amorphous silicon layer film-formed, and a step of forming a gate insulating film on the film-formed amorphous silicon layer. The step of conducting at 600° C. includes a step of activation-treating sources or drains formed in a part of a film-formed silicon layer by ion implantation.

In the formation step of a member for a display panel, in the case that the temperature of the glass laminate of FIG. 1 exceeds 300° C., dehydrocondensation reaction between silanol groups (Si—OH) present on the lamination planes 12a and 14a of the glass substrate 12 and the supporting glass plate 14 is accelerated. For this reason, in the case where the density of silanol groups present on the lamination planes 12a and 14a is too high, it becomes difficult to separate the glass substrate 12 and the supporting glass plate 14 after the formation step of a member of a display panel.

In general, in the case where the density of silanol groups present on the lamination planes 12a and 14a becomes low, bonding force between both the lamination planes 12a and 14a tends to weaken. The reason for this is considered that hydrogen bond between silianol groups present on both the lamination planes 12a and 14a contributes to bonding force of both the lamination planes 12a and 14a. Therefore, in the case where the density of silanol groups present on the lamination planes 12a and 14a is too low, bonding force between both the lamination planes 12a and 14a is too weak, and it is difficult to handle the glass laminate.

That the density of silanol groups present on the lamination planes 12a and 14a is an appropriate range is judged by measuring a water contact angle of the first main surfaces 12a and 14a becoming the lamination planes before lamination. In general, a water contact angle of the glass surface tends to be decreased as density of silanol groups present on the glass surface is increased. The reason for this is considered that a silanol group (Si—OH) contains hydrophilic OH group.

The water contact angle of at least one of the first main surfaces of glass substrate 12 and the supporting glass plate 14 is preferably from 15 to 70°, and more preferably from 15 to 50°. In the case that the water contact angle is less than 15°, the density of silanol groups is too high. On the other hand, in the case that the water contact angle exceeds 70°, the density of silanol groups is too low. In any of the glass substrate 12 and the supporting glass plate 14, the water contact angle of the non-lamination planes 12b and 14b is not limited to the above range.

The glass substrate and the supporting glass plate, having the first main surface are preferably that at least one of the first main surfaces 12a and 14a is surface-treated before lamination to form the first main surface having low density of silanol groups, and those plates are then laminated. This can easily separate the glass substrate 12 and the supporting glass plate 14 in the case where the temperature of the glass laminate exceeds 300° C.

After separation of the glass substrate 12 and the supporting glass plate 14, the glass substrate 12 side becomes a product. For this reason, it is preferred to surface-treat only the first main surface 14a at the supporting glass plate 14 side. In the case where the first main surface 12a at the glass substrate 12 side is surface-treated, disadvantages may occur in a product side, for example, that it is difficult to adhere a polarizing plate to the first main surface 12a after separation.

The first main surface to be surface-treated is preferably a sufficiently clean surface, and is preferably a surface just after cleaning. In the case where cleanness (activity) is too low, uniform surface treatment cannot be performed.

Materials used in the surface treatment include a silane coupling agent and a silicone oil. Those materials are used alone or a combination thereof. In the case of using the materials in combination, surface treatment may be carried out with a silicone oil after surface-treating with a silane coupling agent, and surface treatment may be carried out with a silane coupling agent after surface-treating with a silicone oil.

The silane coupling agent is not particularly restricted. For example, at least one selected from aminosilanes such as hexamethyldisilazne (HMDS), γ-aminopropyltriethoxysilane, N-β-(aminoethyl)-γ-aminopropyltrimethoxysilane, N-β-(aminoethyl)-N′-β-(aminoethyl)-γ-aminopropyltrimethoxysilane and γ-anilinopropyltrimethoxysilane; epoxy silanes such as γ-glycidoxypropyltrimethoxysilane and β-(3,4-epoxycyclohexyl)trimethoxysilane; chlorosilanes such as γ-chloropropyltrimethoxysilane; mercaptosilanes such as γ-mercaptotrimethoxysilane; vinyl silanes such as vinylmethoxysilane and N-β-(N-vinylbenzylaminoethyl)-γ-aminopropyltrimethoxysilane; and acrylsilanes such as γ-methacryloxypropyltrimethoxysilane can preferably be used.

The surface treatment method by a silane coupling agent may be the general method. For example, there is a method of exposing a glass plate to an atmosphere containing a gas obtained by vaporizing a silane coupling agent, and substituting hydrophilic OH group contained in silanol groups (Si—OH) on the glass surface with a hydrophobic group. The density of the silanol groups present on the glass surface can be adjusted by adjusting a concentration of the silane coupling agent in the atmosphere, a temperature, a treatment time and the like.

The silicone oil is not particularly restricted. Examples of the silicone oil include straight silicone oils such as dimethylsilicone oil, methylphenylsilicone oil and methylhydrogensilicone oil; and modified silicone oils having alkyl group, hydrogen group, epoxy group, amino group, carboxyl group, polyether group or the like introduced in a side chain or terminal thereof.

The surface treatment method by the silicone oil may be the general method. For example, there is a method of applying a silicone oil to a glass surface by a spin coater or the like, and baking the silicone oil to the glass surface by heat treatment. The density of silanol groups exposed on the glass surface can be adjusted by adjusting application amount or the like of the silicone oil.

In the case that the surface treatment has been conducted, the density of silanol groups present on the glass surface is decreased, whereby bonding force between both the lamination planes 12a and 14a is decreased.

To supplement decrease in the bonding force by the surface treatment, heat treatment may be conducted in laminating the glass substrate 12 and the supporting glass plate 14. By this, dehydrocondensation reaction between silanol groups present on the both the first main surfaces 12a and 14a is conducted, whereby the bonding force can be increased. To accelerate the dehydrocondensation reaction, heating is preferably conducted such that the temperature of the glass laminate exceeds 300° C. The heating is conducted such that the lamination planes 12a and 14a are not fused.

Furthermore, to supplement decrease in the bonding force by the surface treatment, a part (for example, edge or corner) of the glass substrate 12 and a part of the supporting glass plate 14 may be adhered with an adhesive such as glass fit. This adhesion is conducted such that the lamination planes 12a and 14a are not fused. In peeling the adhered glass substrate 12 and supporting glass plate 14, the adhered part may previously be cut.

In the glass laminate of the present embodiment, the glass substrate 12 and the supporting glass plate 14 are directly contacted and closely adhered through the lamination plane having low density of silanol groups. Therefore, as compared with the case that O-ring or a resin layer is interposed between both the glass plates 12 and 14, the glass laminate is difficult to warp. Therefore, the glass laminate has excellent flatness, and this means that the flatness of the glass substrate surface of the glass laminate is excellent.

The glass laminate of the present embodiment is produced by laminating a glass substrate and a supporting glass plate, similar to the first embodiment, and is preferably produced by laminating the glass substrate and the supporting glass plate in reduced pressure atmosphere. For example, a glass substrate having at least one smooth first main surface is provided, and the glass substrate is cleaned to make water contact angle of at least the first main surface 5° or less. Furthermore, a supporting glass plate having at least one smooth first main surface is provided, and the supporting glass plate is cleaned and then surface-treated to make water contact angle of at least the first main surface from 15 to 70°. Thereafter, those glass substrate and supporting glass plate are placed in a pressing apparatus capable of reducing pressure, those first main surfaces are faced, the inside of the pressing apparatus is made into reduced pressure atmosphere, and those plates are stacked and pressure-contacted, thereby obtaining a glass laminate.

The glass laminate of the present embodiment can be used in the production of a display panel, similar to the first embodiment.

### EXAMPLES

The present invention is specifically described below by reference to Examples and the like, but the invention is not construed as being limited to those Examples. In the Examples, the same glass plates were used as a glass substrate and a supporting glass plate. Therefore, in the following Examples, one of two glass plates constituting a glass laminate is a glass substrate in the present invention, and the other glass plate is a supporting glass plate in the present invention.

### Test Example 1

Three glass plates having 400 mm length×300 mm width×0.4 mm thickness, an average surface roughness of 0.8 nm, and an average linear expansion coefficient at 25 to 300° C. of 38×10⁻⁷/° C. (AN100 manufactured by Asahi Glass Co., Ltd.) were provided. The average surface roughness was measured by an atomic force microscope (manufactured by Pacific Nanotechnology, Nano Scope IIIa; Scan Rate 1.0 Hz, Sample Lines 256, Off-line Modify Flatten order-2, Planefit order-2).

Three glass plates were dipped in 25° C. potassium hydroxide aqueous solution (potassium hydroxide 1 mass %) for 10 minutes, dipped in 25° C. pure water for 10 minutes, dipped in other 25° C. pure water, and subjected to ultrasonic cleaning (36 KHz) for 5 minutes. Thereafter, 80° C. IPA (isopropyl alcohol) vapor was applied to the surfaces of the three glass plates for 10 minutes, followed by drying.

Just after cleaning and drying, 1 μL water droplet was placed on the surface of one glass plate, and a water contact angle was measured using a contact angle meter (manufactured by KRUSS, DROP SHAPE ANALYSIS SYSTEM DSA 10Mk2). As a result, the water contact angle was 4°.

Just after cleaning and drying, the remaining two glass plates 12 and 14 were laminated using a pressing apparatus 30 shown in FIGS. 4A to 4C and FIG. 5, and a glass laminate 10 shown in FIG. 1 was obtained. The lamination was performed under the state that the pressure in a space between both the glass plates 12 and 14 was reduced to −100 kPa (standardized as the atmospheric pressure being zero).

The glass laminate 10 obtained was subjected to the following evaluations.

### (Close Adhesion Test)

The glass laminate 10 was placed on a horizontal plate, the center of the upper side of the glass plate was sucked with a suction pad having a diameter of 20 mm, and the glass laminate was lifted in a rate of 25 mm/second in a vertical direction. As a result, two glass plates 12 and 14 laminated did not separate, and it was seen that there is good close adhesion force.

### (Peeling Test 1)

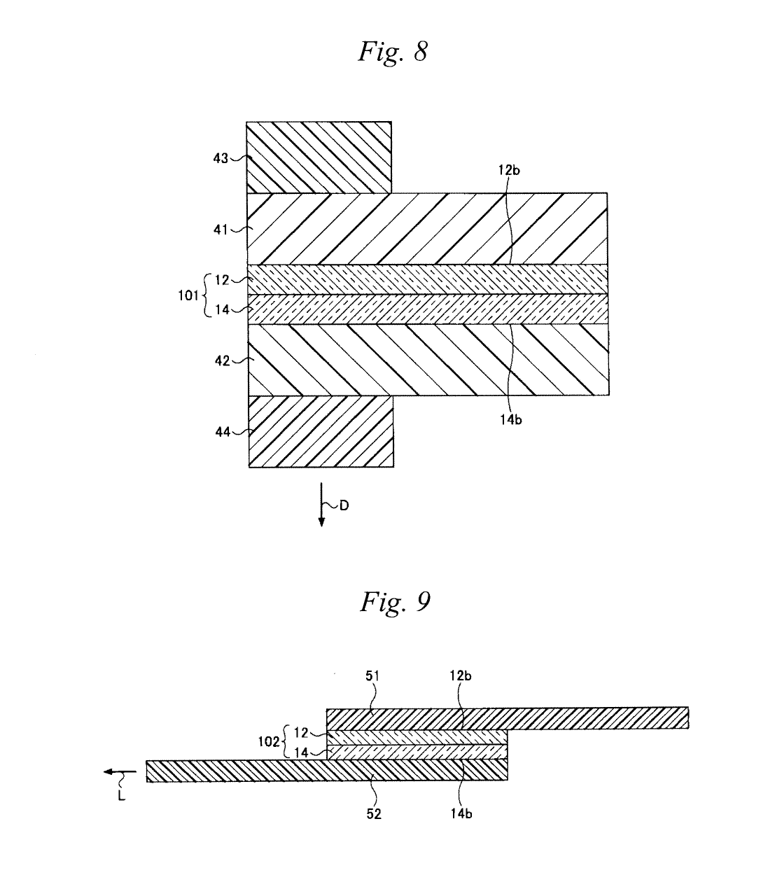

After the close adhesion test, the glass laminate was cut into a plurality of blocks each having 25 mm length×25 mm width. One of those blocks was subjected to a peeling test as shown in FIG. 8 at room temperature without conducting heat treatment. Plate-like members 41 and 42 and knob members 43 and 44 were used as jigs of the peeling test.

The plate-like member 41 has a size of 25 mm length×25 mm width×5 mm thickness, is made of polycarbonate, and is adhered to the second main surface 12b of the glass substrate 12 constituting a block 101 by an epoxy adhesive (not shown). The plate-like member 42 has a size of 25 mm length×25 mm width×5 mm thickness, is made of polycarbonate, and is adhered to the second main surface 14b of the glass substrate 14 constituting a block 101 by an epoxy adhesive (not shown). The plate-like members 41 and 42 are arranged such that the side faces thereof are nearly flush to the side face of the block 101. The adhering areas between the block 101 and the plate-like member 41 and between the block 101 and the plate-like member 42 are 25 mm length×25 mm width, respectively.

The knob member 43 has a size of 25 mm length×10 mm width×5 mm thickness, is made of polycarbonate, and is adhered to a face of the side opposite the glass substrate 12 side of the plate-like member 41 by an epoxy adhesive (not shown). The knob member 44 has a size of 25 mm length×10 mm width×5 mm thickness, is made of polycarbonate, and is adhered to a face of the side opposite the glass substrate 14 side of the plate-like member 42 by an epoxy adhesive (not shown). The knob members 43 and 44 are arranged such that the left side faces thereof are nearly flush to the left side faces of the plate-like members 41 and 42, respectively. The adhering areas between the plate-like member 41 and the knob member 43 and between the plate-like member 42 and the knob member 44 are 25 mm length×10 mm width, respectively.

The block 101 having the jigs 41 to 44 mounted thereon was placed nearly horizontally such that the supporting glass plate 14 faces downside. The knob member 43 adhered to the glass substrate 12 side was fixed, and the knob member 44 adhered to the supporting glass plate 14 side was peeled downward (in D direction of an arrow in the drawing, that is to say, toward a thickness direction of the plate-like members 41 and 42, in a rate of 300 mm/min. As a result, when a load of 0.78N (0.32 N/cm) was applied, two glass plates 12 and 14 laminated were separated. Breakage such as cracks was not observed in both the glass plates 12 and 14 after the separation.

### (Peeling Test 2)

Of a plurality of blocks, other block was heat-treated at a temperature of 300° C. for 1 hour in the atmosphere, cooled to room temperature, and then subjected to a peeling test shown in FIG. 8. As a result, when a load of 0.78N (0.32 N/cm) was applied, two glass plates 12 and 14 laminated were separated. Breakage such as cracks was not observed in both the glass plates 12 and 14 after the separation.

### (Peeling Test 3)

Other block was heat-treated at a temperature of 450° C. for 1 hour in the atmosphere, cooled to room temperature, and then subjected to a peeling test shown in FIG. 8. As a result, two glass plates 12 and 14 were not separated until one of those plates is broken.

### (Heat-Resistant Test)

Other block was heat-treated at a temperature of 450° C. for 1 hour using a hot plate, and the state of the block was observed. As a result, gas bubbles were not observed between two glass plates laminated, and breakage such as cracks was not observed in both glass plates.

### (Shear Test 1)

Other block was subjected to a shear test shown in FIG. 9 at room temperature. Plate-like members 51 and 52 were used as the jigs of the shear test.

The plate-like member 51 has a size of 25 mm length×50 mm width×3 mm thickness, is made of polycarbonate and is adhered to the second main surface 12b of the glass substrate 12 constituting the block 102 by an epoxy adhesive (not shown). The plate-like member 51 was arranged such that the left side face thereof is nearly flush to the left side face of the block 102. The adhering area between the block 102 and the plate-like member 51 is 25 mm length×25 mm width. The plate-like member 52 has a size of 25 mm length×50 mm width×3 mm thickness, is made of polycarbonate and is adhered to the second main surface 14b of the supporting glass plate 14 constituting the block 102 by an epoxy adhesive (not shown). The plate-like member 52 was arranged such that the right side face thereof is nearly flush to the right side face of the block 102. The adhering area between the block 102 and the plate-like member 52 is 25 mm length×25 mm width.

The block 102 having the jigs 51 and 52 is arranged nearly horizontally such that the supporting glass plate 14 faces downward. The plate-like member 51 adhered to the glass substrate 12 side was fixed, and the plate-like member 52 adhered to the supporting glass plate 14 side was pulled in a left direction which is L direction of an arrow in FIG. 9, that is to say, toward a longitudinal direction of the plate-like members 51 and 52, in a rate of 0.5 mm/min. As a result, when a load of 118N (19 N/cm²) was applied, one of two glass plates 12 and 14 laminated was broken. Deviation was not observed between both glass plates 12 and 14 until one of both glass plates was broken.

As is apparent from the results of the peeling test 1 and the shear test 1, two glass plates 12 and 14 laminated are peeled with relatively weak force in a vertical direction of the lamination plane, and are difficult to shift to an in-plane direction of the lamination plane even though relatively strong force is applied. Therefore, the glass plates 12 and 14 can easily be separated, and the lamination plane can be suppressed from deviating in, for example, transporting the glass laminate 10.

### (Shear Test 2)

Other block was heat-treated at a temperature of 300° C. for 1 hour in the atmosphere, cooled to room temperature and subjected to a shear test shown in FIG. 9. As a result, one of two glass plates 12 and 14 laminated was broken when a load of 118N (19 N/cm²) was applied. Deviation was not observed in both glass plates 12 and 14 until one of both glass plates was broken.

### Test Example 2

A glass laminate was produced in the same manner as in Test Example 1, except that two glass plates were laminated at room temperature in the atmosphere by pushing by hand, in place of using the pressing apparatus 30 shown in FIGS. 4A to 4C and FIG. 5.

The glass laminate produced was subjected to the close adhesion test in the same manner as in Test Example 1. As a result, it was seen that two glass plates laminated do not separate, and there is good close adhesion force.

After the close adhesion test, peeling test 1 was conducted in the same manner as in Test Example 1. As a result, two glass plated laminated were separated when a load of 0.80N (0.32 N/cm) was applied. Breakage such as cracks was not observed in both glass plates after the separation.

As a result of conducting peeling test 2, two glass plated laminated were separated when a load of 0.75N (0.30 N/cm) was applied. Breakage such as cracks was not observed in both glass plates after the separation.

As a result of conducting peeling test 3, two glass plated laminated were not separated until one of those was broken.

As a result of conducting heat-resistant test, large gas bubbles were observed between two glass plates laminated. This is presumed that because lamination was conducted in the atmosphere, fine gas bubbles were bitten during lamination.

### Test Example 3

In Test Example 3, a glass laminate was produced in the same manner as in Test Example 1, except that the period of from the cleaning and drying of the glass plate to the lamination was one week. One week later from the cleaning and drying, a water contact angle of the glass plate was measured using the contact angle meter. As a result, the water contact angle was 10°.

The glass laminate produced was subjected to the close adhesion test in the same manner as in Test Example 1. As a result, it was seen that two glass plates laminated do not separate, and there is good close adhesion force.

After the close adhesion test, peeling test 1 was conducted in the same manner as in Test Example 1. As a result, two glass plated laminated were separated when a load of 0.75N (0.30 N/cm) was applied. Breakage such as cracks was not observed in both glass plates after the separation.

As a result of conducting peeling test 2, two glass plated laminated were separated when a load of 0.75N (0.30 N/cm) was applied. Breakage such as cracks was not observed in both glass plates after the separation.

As a result of conducting peeling test 3, two glass plated laminated were not separated until one of those was broken.

### Test Example 4

In Test Example 4, a glass laminate was produced in the same manner as in Test Example 3, except that two glass plates were laminated at room temperature in the atmosphere by pushing by hand, in place of using the pressing apparatus 30 shown in FIGS. 4A to 4C and FIG. 5.

The glass laminate produced was subjected to the close adhesion test in the same manner as in Test Example 1. As a result, it was seen that two glass plates laminated are separated, and are not sufficiently closely adhered.

### Test Examples 5 to 8

In Test Examples 5 to 8, glass laminates were produced in the same manner as in Test Example 1, except that, of the first main surfaces of two glass plates, only one first main surface was subjected to surface treatment with a silane coupling agent just after the cleaning and drying and just before the lamination.

Hexamethyldisilazne (1,1,1,3,3,3-hexamethyldisilazane, manufactured by Kanto Chemical Co., Inc.) was used as the silane coupling agent. The glass plate was exposed to an atmosphere containing a gas obtained by evaporating the silane coupling agent to conduct a surface treatment.

The time of conducting the surface treatment, the water contact angle of glass surface just after the surface treatment, and the results of close adhesion test and peeling tests 1 to 3 after lamination are shown in Table 1. As the judgment standard of the close adhesion test, the case that two glass plates laminated were not separated was designated as “◯”, and the case that two glass plates laminated were separated was designated as “X”. As the judgment standard of peeling tests 1 to 3, the case that two glass plates laminated had peel strength of 0.2 N/cm or more and were not broken after peeling was designated as “◯”, the case that two glass plates laminated were broken before peeling was designated as “X”, and the case that the two glass plates laminated had small peel strength and could not be subjected to peeling tests 1 to 3 was designated as “-”.

TABLE 1

| | Treatment | Water | Close | Peeling test 1 | | |
|---|---|---|---|---|---|---|
| | time | contact angle | adhesion | (room | Peeling test 2 | Peeling test 3 |
| | (min) | (°) | test | temperature) | (300° C.) | (450° C.) |
| Test Example 5 | 1 | 18 | ◯ | ◯ | ◯ | ◯ |
| Test Example 6 | 5 | 33 | ◯ | ◯ | ◯ | ◯ |
| Test Example 7 | 10 | 59 | ◯ | ◯ | ◯ | ◯ |
| Test Example 8 | 15 | 76 | X | — | — | — |

### Test Examples 9 to 11

In Test Examples 9 to 11, glass laminates were produced in the same manner as in Test Example 1, except that, of the first main surfaces of two glass plates, only one first main surface was subjected to surface treatment with a silane coupling agent just after the cleaning and drying and just before the lamination.

A method of exposing the glass plate to an atmosphere containing a gas obtained by vaporizing the silane coupling agent (Z6040 manufactured by Dow Corning Toray Co., Ltd.) was used as the surface treatment method.

The time of conducting the surface treatment, the water contact angle of glass surface just after the surface treatment, and the results of close adhesion test and peeling tests 1 to 3 after lamination are shown in Table 2. The judgment standard of the close adhesion test and the judgment standard of peeling tests are the same as in Table 1, and the explanation thereof is omitted.

TABLE 2

| | Treatment | Water | Close | Peeling test 1 | | |
|---|---|---|---|---|---|---|
| | time | contact angle | adhesion | (room | Peeling test 2 | Peeling test 3 |
| | (min) | (°) | test | temperature) | (300° C.) | (450° C.) |
| Test Example 9 | 5 | 43 | ◯ | ◯ | ◯ | ◯ |
| Test Example 10 | 10 | 97 | X | — | — | — |
| Test Example 11 | 15 | 107 | X | — | — | — |

### Test Examples 12 to 13

In Test Examples 12 to 13, glass laminates were produced in the same manner as in Test Example 1, except that, of the first main surfaces of two glass plates, only one first main surface was subjected to surface treatment with a silicone oil just after the cleaning and drying and just before the lamination.

Dimethylsilicone oil (SH 200, dimethylpolysiloxane, manufactured by Dow Coring Toray Co., Ltd.) was used as the silicone oil. First, a solution obtained by diluting the silicone oil with heptane was applied to a glass surface using a spin coater (MS-A100 manufactured by Mikasa Co., Ltd.). Heat treatment was conducted at a temperature of 500° C. for 5 minutes in the atmosphere using a hot plate. Thus, the surface treatment of baking the silicone oil on the glass surface was conducted.

The time of conducting the surface treatment, the water contact angle of glass surface just after the surface treatment, and the results of close adhesion test and peeling tests 1 to 3 after lamination are shown in Table 3. The judgment standard of the close adhesion test and the judgment standard of peeling tests are the same as in Table 1, and the explanation thereof is omitted.

TABLE 3

| | Treatment | Water | Close | Peeling test 1 | | |
|---|---|---|---|---|---|---|
| | time | contact angle | adhesion | (room | Peeling test 2 | Peeling test 3 |
| | (min) | (°) | test | temperature) | (300° C.) | (450° C.) |
| Test Example 12 | 5 | 41 | ◯ | ◯ | ◯ | ◯ |
| Test Example 13 | 20 | 100 | X | — | — | — |

As is apparent from Tables 1 to 3, it was seen that when a water contact angle of a glass surface is appropriately set and density of silanol groups present on the glass surface is appropriately set, two glass plates constituting a glass laminate can be peeled by a given operation even in the case that the glass laminate was heat-treated at a temperature of 450° C. for 1 hour.

Although the present invention has been described in detail and by reference to the specific embodiments, it is apparent to one skilled in the art that various modifications or changes can be made without departing the spirit and scope of the present invention.

This application is based on Japanese Patent Application No. 2009-241797 filed on Oct. 20, 2009, the disclosure of which is incorporated herein by reference.

### INDUSTRIAL APPLICABILITY

According to the present invention, a glass laminate having excellent flatness and a production method thereof can be provided. Furthermore, according to the present invention, a production method of a display panel using the glass laminate and a display panel obtained by the production method can be provided.

### DESCRIPTION OF REFERENCE NUMERALS AND SIGNS

10: Glass laminate
12: Glass substrate
12a: First main surface
12b: Second main surface
14: Supporting glass plate
14a: First main surface
14b: Second main surface
22: Depressed portion

1. A glass laminate comprising a glass substrate and a supporting glass plate, in which a surface of the glass substrate and a surface of the supporting glass plate are directly contacted to each other,
wherein each of the surface of the glass substrate and the surface of the supporting glass plate that are contacted to each other is a smooth flat surface, and the both surfaces are closely adhered.

2. The glass laminate according to claim 1, wherein the glass substrate and the supporting glass plate are separable by conducting an operation for separating them.

3. The glass laminate according to claim 1, wherein average surface roughnesses (Ra) before contacting of the both surfaces contacted to each other are less than 1.0 nm, respectively.

4. The glass laminate according to claim 1, wherein water contact angles before contacting of the both surfaces contacted to each other are 5° or less, respectively.

5. The glass laminate according to claim 1, wherein at least one of water contact angles before contacting of the both surfaces contacted to each other is from 15 to 70°.

6. The glass laminate according to claim 1,
wherein a thickness of the glass substrate is 0.04 mm or more and less than 0.8 mm,
a thickness of the supporting glass plate is 0.08 mm or more, and
a total thickness of the glass substrate and the supporting glass plate is 0.2 mm or more and 1.0 mm or less.

7. The glass laminate according to claim 1, wherein difference in an average linear expansion coefficient at from 25° C. to 300° C. between the glass substrate and the supporting glass plate is 15×10⁻⁷/° C. or less.

8. The glass laminate according to claim 1,
wherein the supporting glass plate has a depressed portion at a peripheral part of a face at the side contacting the glass substrate, and
the depressed portion is sealed with the glass substrate.

9. The glass laminate according to claim 1, wherein a member for a display panel is formed on a face of the glass substrate at the side opposite the side contacting the supporting glass plate.

10. A method for producing the glass laminate according to claim 1,
the method comprising laminating the glass substrate and the supporting glass plate in reduced pressure atmosphere.

11. The method for producing a glass laminate according to claim 10, wherein at least one surface of the surface of the glass substrate and the surface of the supporting glass plate, becoming lamination planes is cleaned before lamination.

12. The method for producing a glass laminate according to claim 11, wherein at least one of the surfaces after cleaning is surface-treated before lamination.

13. The method for producing a glass laminate according to claim 12, wherein a material of the surface treatment contains a silane coupling agent or a silicone oil.

14. The method for producing a glass laminate according to claim 10, wherein the glass substrate and the supporting glass plate are laminated while supporting a peripheral part of a non-lamination plane of the glass substrate.

15. A method for producing a display panel using the glass laminate according to claim 1, the method comprising:
forming a member for a display on a face of the glass substrate at the side opposite the side contacting the supporting glass plate, and
subsequently separating the glass substrate and the supporting glass plate.

16. The method for producing a display panel according to claim 15, wherein the member for a display panel is a thin film transistor.

17. The method for producing a display panel according to claim 15, wherein the member for a display panel is a color filter.

18. A display panel obtained by the method for producing a display panel according to claim 15.
